(19) United States
(12) Patent Application Publication
(10) Pub. No.: US 2023/0187331 A1
(43) Pub. Date: Jun. 15, 2023

(54) INTERPOSER WITH A GLASS CORE THAT INCLUDES OPENINGS AND THROUGH GLASS VIAS

(71) Applicant: Intel Corporation, Santa Clara, CA (US)

(72) Inventors: Bainye Francoise ANGOUA, Phoenix, AZ (US); Chelsea GROVES, Chandler, AZ (US); Frank TRUONG, Gilbert, AZ (US); Praneeth AKKINEPALLY, Tempe, AZ (US); Whitney BRYKS, Tempe, AZ (US)

(21) Appl. No.: 17/549,497

(22) Filed: Dec. 13, 2021

(51) Int. Cl. H01L 23/498; H01L 21/48; H01L 23/15

(52) U.S. Cl. CPC H01L 23/49827; H01L 21/486; H01L 23/15; H01L 23/49838; H01L 23/49866

(57) ABSTRACT

Embodiments herein relate to systems, apparatuses, or processes directed to a package that includes a glass core with one or more openings with one or more dies placed in the opening such that the glass core surrounds the one or more dies. One or one or more through glass via filled with conductive material such as copper electrically couple a first side of the glass core with a second side of the glass core opposite the first side. Other embodiments may be described and/or claimed.

### FIELD

Embodiments of the present disclosure generally relate to the field of package assemblies, and in particular to package assemblies that include glass cores with openings to include one or more die.

### BACKGROUND

Continued reduction in the end-product size of mobile electronic devices, such as smart phones and ultrabooks, is a driving force for package miniaturization and component quality increase.

### BRIEF DESCRIPTION OF THE DRAWINGS

FIG. 1 illustrates a cross section side view of a glass core that includes one or more openings and a plurality of through glass vias (TGV) that are filled with copper, in accordance with various embodiments.

FIG. 2 illustrates a top-down view of the glass core that includes one or more openings, in accordance with various embodiments.

FIG. 3 illustrates a cross-section side view of a legacy interposer package that uses an organic core.

FIG. 4 illustrates a cross-section side view of an interposer package that includes a glass core, in accordance with various embodiments.

FIGS. 5A-5I illustrates stages in a manufacturing process for creating an interposer package that includes a glass core with an opening and TGVs, in accordance with various embodiments.

FIG. 6 illustrates an example of a process for creating a glass core with an opening and TGVs, in accordance with various embodiments.

FIG. 7 illustrates multiple examples of laser-assisted etching of glass interconnects processes, in accordance with embodiments.

FIG. 8 schematically illustrates a computing device, in accordance with embodiments.

### DETAILED DESCRIPTION

Embodiments of the present disclosure may generally relate to systems, apparatus, techniques, and/or processes directed to a package that includes a glass core with one or more openings, which may also be referred to as a window or a cut out, within the glass core. In embodiments, the package may be referred to as an interposer. In embodiments, one or more dies, may be placed in an opening within the glass core, such that the glass core creates a patch-like architecture that at least partially surrounds the one or more dies.

In embodiments, one or more TGV may be filled with conductive material, such as copper, and electrically couple a first side of the glass core with a second side of the glass core opposite the first side. In embodiments, the glass core with the one or more dies may be generally referred to as an embedded die architecture. In embodiments, during manufacturing of the package the glass core and the TGV filled with conductive material may be prefabricated, and then added as a single manufacturing stage within the manufacturing process. In embodiments, during manufacturing the one or more dies may be electrically coupled with one of the one or more TGV.

In embodiments, a thickness of the glass core and a thickness of the one or more dies may be a similar thickness. Thus, after the one or more die are inserted within the openings of the glass core, the top and the bottom of the resulting combination structure may be substantially planar. In embodiments, a coefficient of thermal expansion (CTE) for the glass core and a CTE of one or more dies may be selected to be substantially similar. Similar CTE for the glass core and the one or more dies may minimize mechanical stress and/or warpage when heat is generated during package manufacture or during operation the package. Additionally, the composition of the glass may include any number of additional elements to alter its thermomechanical and electrical properties; it may range from pure SiO₂ to >50% substituted with alternate elements.

In embodiments, the combination structure may be highly planar, due in part to the flatness of the sides of the glass core. In addition, the combination structure will also have strength and be able to resist thermomechanical stress due to the strength of the glass material within the glass core. A thickness of the glass core and/or composition of the glass within the glass core may be chosen to provide a variety of different design architectures for diverse performance parameters during package operation. For example, integrated passive devices using wafer material other than Si may have appropriately matching CTE selected by the glass composition, and devices with critical dimensions either thick or thin may be accommodated by glass thinning. In addition, during manufacture the glass core and the one or more die may be placed upon a carrier to enhance planarity during the manufacturing process. The carrier may be glass, fused silica, stainless steel or the like.

In embodiments, a thickness of the one or more dies may require copper pillars to be created around the one or more dies. This may be accomplished through the one or more TGV through the glass core that are filled with conductive material. These TGVs may be placed in proximity to the one or more dies. In embodiments, the one or more TGV may be very high aspect ratio TGV, with a height of the TGV up to 15 times the diameter of the TGV, which is enabled using a glass core. In addition, the pitch of the TGV may also be very close, for example on the order of 25 μm. Techniques for manufacturing embodiments may include fewer process stages as compared to legacy manufacturing process implementations. In addition, embodiments may optimize package yield by using a glass core, which also functions as a package stiffener, that has pre-formed cavities and copper TGVs, thus reducing warpage and planarity issues during manufacture.

In embodiments, active dies may be placed into the glass core openings. In embodiments, an embedded die such as an interconnect bridge die (e.g., embedded multi-die interconnect Bridge (EMIB)), or an assembly including one or more interconnect bridges as well as through interconnects (e.g., copper pillars) arranged adjacent the interconnect bridges (e.g, an omni-directional interconnect (ODI) assembly) may be placed within the glass core openings. In embodiments, the glass core and TGVs may serve as a patch, providing no pitch translation between components above the glass core and below the glass core. Subsequent to the manufacturing process, a first level interconnect (FLI) for an active die may be formed on one side of the glass core, and a mid-level interconnect (MLI) may be formed on the other side of the glass core to connect to an organic interposer substrate. In some embodiments, a redistribution layer (RDL) may be formed on one or both sides of the glass core to aid in signal routing or power routing.

In legacy implementations, one or more dies are embedded within an organic substrate instead of within a glass core. In these legacy implementations, because the thickness of the embedded die requires copper pillars to be created around it, a thick photoresist plating and then dielectric backfill are needed to embed the one or more dies. This is a complex process that results in yield loss. Another legacy implementation includes the creation of a cavity within dielectric by laser ablation of the dielectric, which is a slow and costly process. In addition, in these legacy implementations, the planarity of the copper pillars and embedded die pads and/or die bumps may be challenging, which necessitates costly additional processes such as chemical mechanical polishing (CMP) and/or mechanical grinding to achieve planarity. In addition, planarity in these legacy implementations may be further challenged by warpage inherent with using organic substrates to surround the one or more dies.

In legacy implementations, placing copper pillars around the one or more dies may be done by pre-fabricating copper pillars and using a pick and place process to place the copper pillars on a substrate. The copper pillars then also be plated within a photoresist, and then the surrounding space filled with a dielectric that embeds the one or more dies. These legacy processes may result in some throughput issues associated with the slow pick and place process. There will also be quality issues due to pillar shifting in subsequent manufacturing stages. Additionally, legacy tall copper pillar plating techniques involve additional cost, and may also result in highly variable bump heights that may be attributed to uneven copper plating rates.

Embodiments described herein may provide an efficient and cost-effective way of disaggregating what would otherwise be a single legacy package into separate portions, and electrically and physically coupling the separate portions in a high-speed, high-bandwidth manner using glass core technology. This architecture will increase yield through the benefit of disaggregation and improve assembly yield through the benefit of CTE matching leading to better bump coplanarity between die and glass interposer, and increase reliability by providing increased package stiffness, reduced warpage, and reduced mechanical stress

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

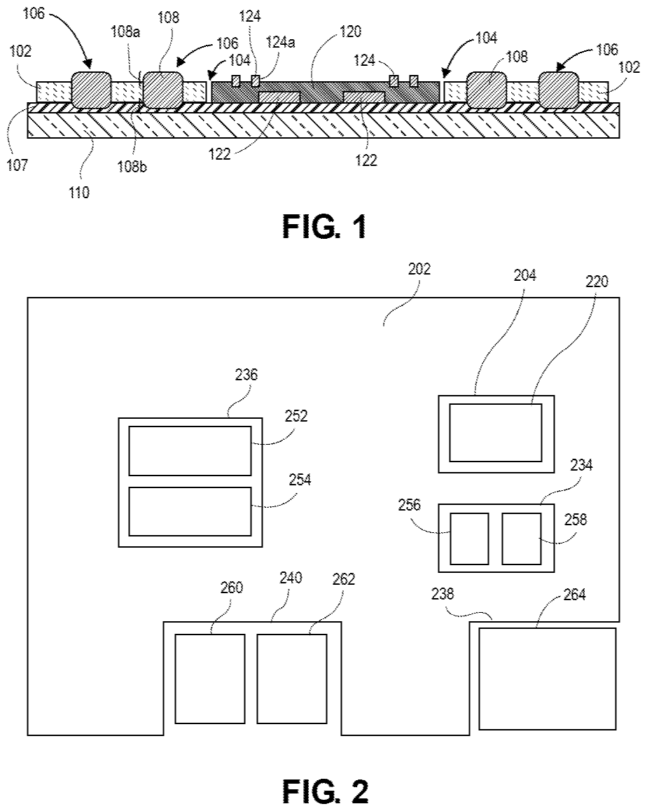

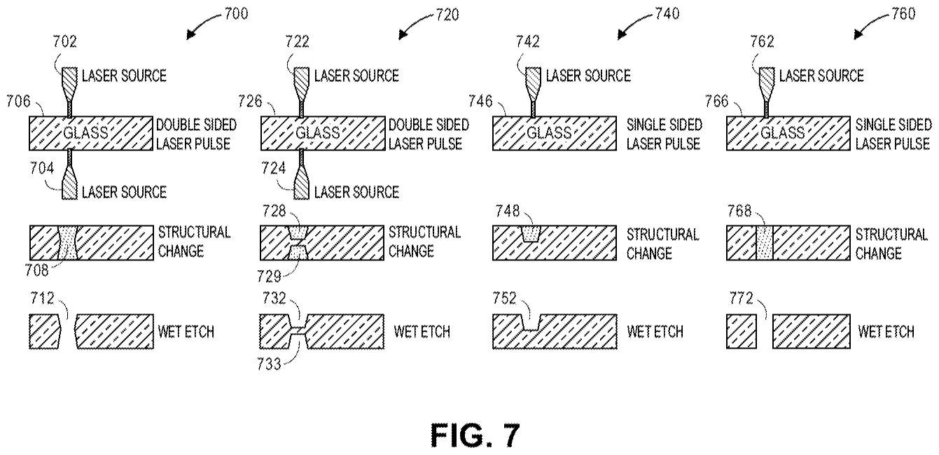

FIG. 1 illustrates a cross section side view of a glass core that includes one or more openings and a plurality of TGV that are filled with copper, in accordance with various embodiments. During manufacture, the one or more openings 104 and the TGVs 106 may be cut out using a laser or using etching techniques. This may include using the techniques as described below with respect to FIG. 7. Glass core 102, which includes opening 104 within the glass core 102 is placed on a carrier 110. In embodiments, the carrier 110 may be a glass carrier. In embodiments, there is a laser release layer (LRL) 107 that bonds one side of the glass core 102 to one side of the carrier 110. In embodiments, the LRL 107 may be a temporary bonding film or adhesive (TBF) that will be subsequently released during the manufacturing process.

The TGVs 106 extend from a first side of the glass core 102 to a second side of the glass core 102 opposite the first side. A conductive material 108 fills the plurality of TGVs 106, with a portion of the conductive material 108a, 108b extending beyond the first side and/or the second side of the glass core 102. During the manufacturing process, the glass core 102, TGVs 106, and conductive material 108 may be pre-manufactured.

A die 120 may be inserted within the opening 104 within the glass core 102. The die 120 may include one or more electrical contacts 122 on a first side of the die, and one or more electrical contacts 124 on a second side of the die opposite the first side. Note that in embodiments, a portion of the electrical contact 124a may extend beyond the side of the die 120. In embodiments, a thickness of the die 120 and a thickness of the glass core 102 may be similar, and may be on the order of 100 to 500 μm in thickness. In embodiments, the thickness of the glass core 102 may be adjusted to be consistent with the height of the die 120. In embodiments, as shown in greater detail respect to FIG. 2, die 120 may be a plurality of dies.

In embodiments, die 120 and glass core 102 may be designed to have a similar CTE. A similar CTE may minimize warpage and other mechanical stresses between the die 120 and the glass core 102 during operation, or when they are otherwise in an increased thermal state. In embodiments, the glass core 102 may have a varied material composition in order to adjust the CTE. For example, a very low CTE may be achieved if the glass is quartz or a silicon dioxide structure. In embodiments, the CTE may range from below 1 to 12. In legacy implementations where an organic material is used instead of the glass core 102, the significantly higher CTE of the organic material will cause a mismatched with the CTE of the die and result in mechanical stress on the legacy package, including dies that are deformed/bowed that may result in a height mismatch with the organic material.

FIG. 2 illustrates a top-down view of the glass core that includes one or more openings, in accordance with various embodiments. Glass core 202, which may be similar to glass core 102 of FIG. 1, includes a plurality of openings 204, 234, 236, which may be similar to opening 104 of FIG. 1, that are entirely within the glass core 202. Glass core 202 may also include openings 238, 240 that are at an edge of the glass core 202. Note that for ease of viewing, the TGV, such as TGV 106 of FIG. 1, are not shown.

An opening 204 may include a single die 220, which may be similar to die 120 of FIG. 1. An opening 236 may include multiple dies 252, 254 in a first orientation, and opening 234 may include multiple dies 256, 258 in a second orientation different from the first orientation. In embodiments, an opening such as opening 236 may include three or more dies. Opening 240 may include dies 260, 262, each having two edges that are proximate to an edge of the glass core 202. Opening 238 may include a die 264, with two edges that are proximate to an edge of the glass core 202.

Although non-limiting examples of configurations of openings 204, 234, 236, 238, 240 within the glass core 202 are shown, any opening size or shape may be created within the glass core 202. This may include, for example but not limited to, rectangles with rounded corners, circles, ovals, or any other regular or irregular shapes.

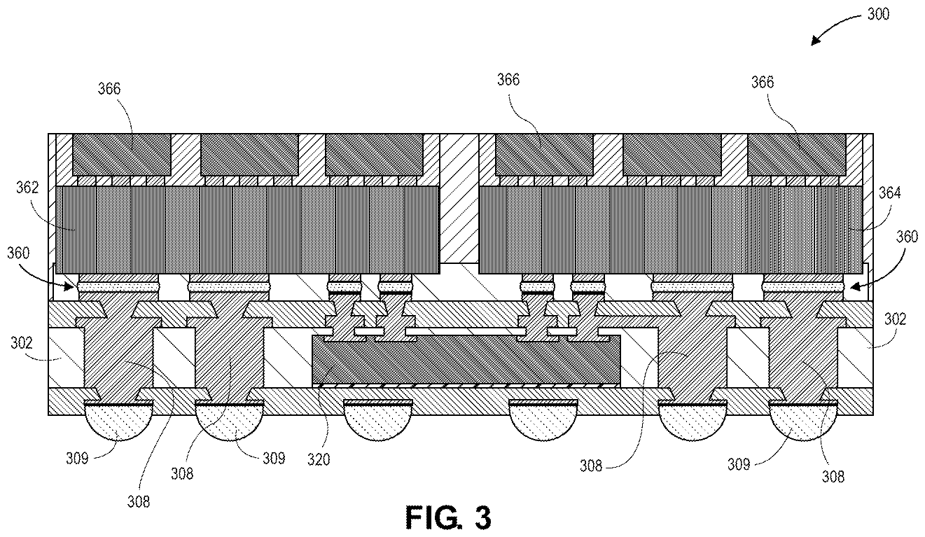

FIG. 3 illustrates a cross-section side view of a legacy interposer package that uses an organic core. Legacy package 300 includes a core 302 that is a non-glass core that surrounds an active die 320, which may be similar to die 120 of FIG. 1. A plurality of copper pillars 308 are used to electrically couple a first side of the non-glass core 302 with a second side of the non-glass core 302 opposite the first side. In legacy implementations, the copper pillars 308 may be coupled with a plurality MLI bumps 309. MLI bumps 309 may be used to physically and electrically couple the legacy package 300 with a substrate (not shown).

The active die 320 may be electrically coupled with a second die 362 and a third die 364 through a FLI interface 360. Both the second die 362 and the third die 364 are above the active die 320. The active die 320 may also be electrically coupled with TSVs 308, for example, for power and/or signal transmission. In legacy implementations, the second die 362 and the third die 364 may be interposer dies that are in turn electrically and physically coupled with a number of chiplets 366.

During the manufacture of legacy package 300, the active die 320 is embedded within the core 302, which may be a dielectric. Stages in the legacy manufacturing process, include creating a cavity within the dielectric, typically by laser ablation, which may be a slow and costly process. In addition, legacy manufacturing that involves forming and placing the copper pillars 308 is a complex process with quality control challenges. As a result, in legacy implementations, pads within the FLI 360 and/or bumps 309 may be non-planar, and require CMP or mechanical grinding processing to bring them within tolerances. In addition, a CTE mismatch between the CTE of the core 302 and the CTE of the active die 320 will result in warpage and mechanical stress resulting from thermal gradients during legacy package 300 manufacturing and operation.

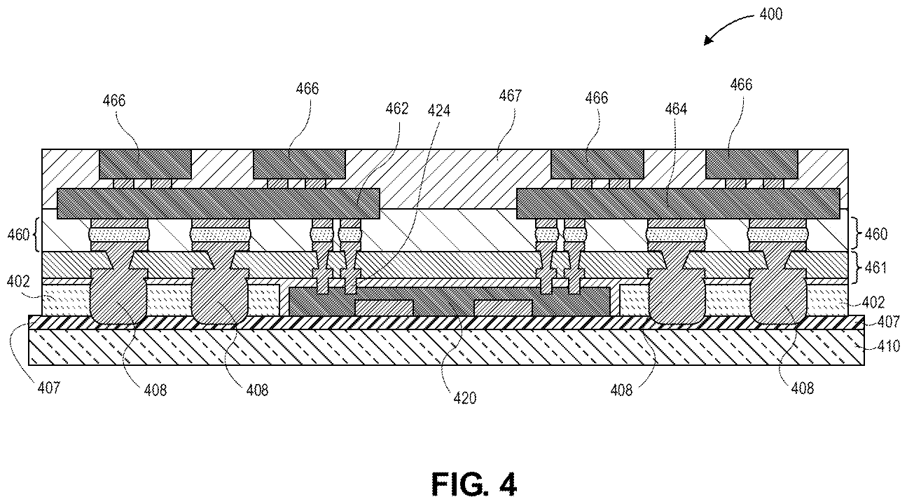

FIG. 4 illustrates a cross-section side view of an interposer package that includes a glass core, in accordance with various embodiments. Package 400 includes a glass core 402, a die 420 within an opening within the glass core 402, with a plurality of TGV 408 filled with copper that extend from a first side of the glass core 402 to the second side opposite the first side. The glass core 402 may be coupled to a carrier 410, and may be temporarily secured to the glass carrier 410 by a LRL 407 that bonds one side of the glass core 402 to one side of the glass carrier 410. In embodiments, the LRL 407 may be a TBF. The glass core 402, the TGV 408 filled with copper, the glass carrier 410, the die 420, and the LRL 407 may be similar to glass core 102, TGV 108, glass carrier 110, die 120, and LRL 107 of FIG. 1.

Embodiments, the die 420 may include electrical contacts 424, which may be similar to contacts 124 of FIG. 1, to electrically couple the die 420 with other components in the package 400. A dielectric layer 461 may be placed on a side of the glass core 402 and the die 420. The dielectric layer 461 may include electrical couplings within the layer 461 to connect with a FLI layer 460. In embodiments, the FLI layer 460 may be electrically and physically coupled with a second die 462 and a third die 464. In embodiments, the second die 462 and the third die 464 may be interposers electrically and physically coupled with chiplets 466. In embodiments, the upper portion of the package 400 may be encased within a mold 467 that may surround the second die 462, third die 464, and chiplets 466.

Note that after the removal of the carrier 410 and the LRL 407 from the package 400, a series of bumps in an MLI layer (not shown, but similar to bumps 309 of FIG. 3) may be used to physically and electrically couple the package 400 with a substrate. In embodiments, an RDL (not shown) may be applied to a side of the glass core 402 to provide pitch translation and to fanout the series of bumps in an MLI layer (not shown). Note that the glass core 402 will provide structural rigidity for the package 400, as well as to provide planarity for any RDL (not shown) that may be subsequently applied. In embodiments, the FLI interconnection may be done first to maximize assembly yield, for example for best flatness, prior to removing the underlying carrier, and lastly applying the MLI, including forming any bottom RDL if needed.

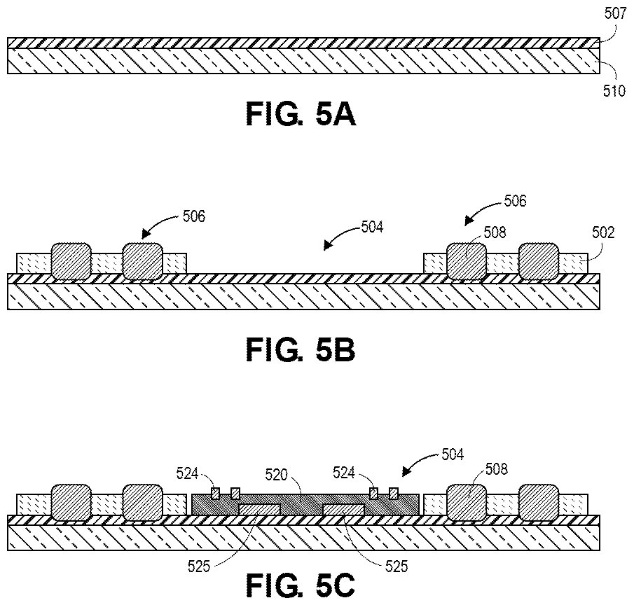

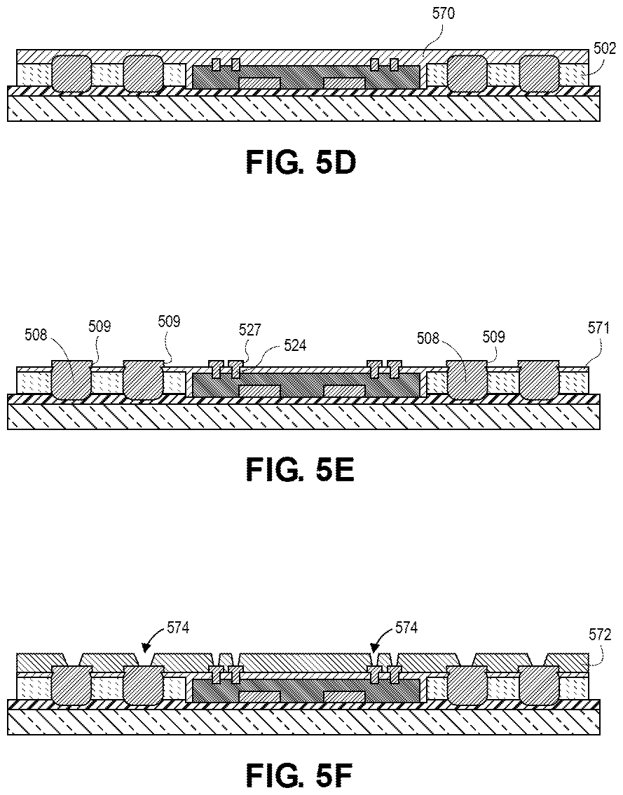

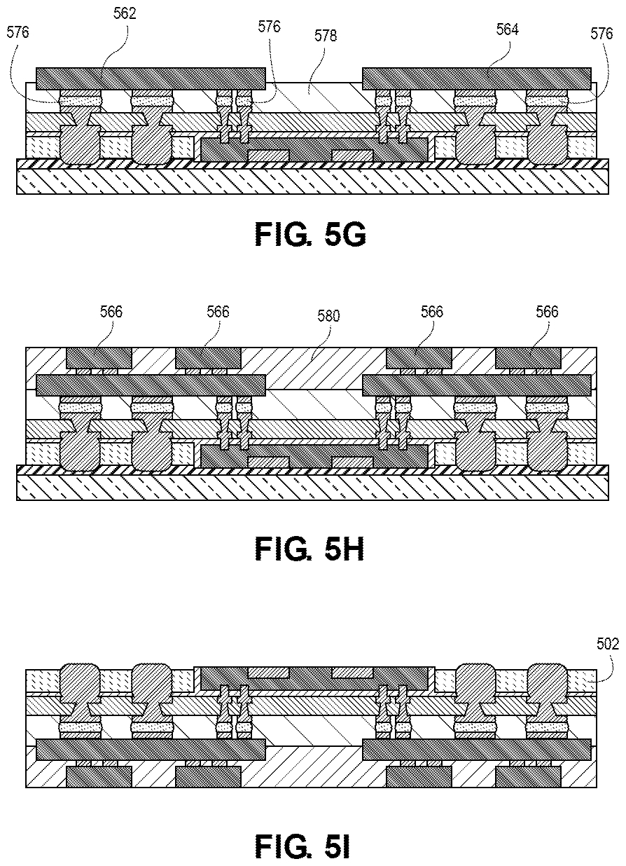

FIGS. 5A-5I illustrates stages in a manufacturing process for creating an interposer package that includes a glass core with an opening and TGVs, in accordance with various embodiments. FIG. 5A illustrates a stage in the manufacturing process where a glass carrier 510 is provided, and a LRL 507 is placed on a surface of the glass carrier 510. In embodiments, glass carrier 510 and LRL 507 may be similar to glass carrier 410 and LRL 407 of FIG. 4. In embodiments, the glass carrier 510 is used to provide a flat and stable surface for subsequent stages of manufacturing. A thickness of the glass carrier 510 may be chosen based on the manufacturing requirements and stresses that may be placed on the glass carrier 510 during subsequent stages of the manufacturing process.

In embodiments, the LRL 507 may have a thickness required to achieve a continuous and void-free bond between the glass carrier 510 and subsequent application of the glass core 502 as described with respect to FIG. 5B. In embodiments, the LRL 507 may be multiple layers. In embodiments, a thicker LRL 507 may allow for the copper 508 described with respect to FIG. 5B in the glass core 502 to have an overburden and still adhere to the glass carrier 510. In embodiments, the LRL 507 may be an adhesive TBF. In some embodiments, a thickness of the LRL 507 may be in the order of 5-50 μm.

FIG. 5B illustrates a stage in the manufacturing process where a glass core 502 that includes an opening 504 and TGVs 506 that are filled with copper 508 that extend from a first side of the glass core 502 to a second side of the glass core 502 opposite the first side. The copper 508 electrically couple the first side and the second side of the glass core 502. In embodiments, the glass core 502 the TGV 506 and the copper 508 may be prefabricated at a separate stage of the manufacturing process, and then subsequently applied to the LRL 507 in a single stage. Note that in embodiments, volumes of the copper 508 may extend beyond the sides of the glass core 502. The glass core 502 may be similar to glass core 102 of FIG. 1.

In embodiments, the opening 504 may be formed by wet etching, dry etching, or a laser process. Other processes may include photo-definable glass, where the opening 504 may be defined by using a lithography exposure process followed by wet etching, to provide a lithography alignment of multiple openings that may be formed within the glass core 502. In embodiments, the openings may be created using the laser-assisted etching of glass interconnects process as described below with respect to FIG. 7.

FIG. 5C illustrates a stage in the manufacturing process where a die 520, which may be similar to die 120 of FIG. 1, is inserted within the opening 504. In embodiments, the die 520 will be physically coupled with the LRL 507. The die 520 includes electrical contacts 524, which may be similar to electrical contacts 124 of FIG. 1, which may protrude beyond a surface of the die 520. In embodiments, there may be electrical contacts 525 that extend from the opposite side of the die 520 and to the LRL 507. In embodiments, the die 520 may be an interposer die or an interconnect bridge die, or an integrated passive device like a capacitor or inductor.

FIG. 5D illustrates a stage in the manufacturing process where an over mold 570 is applied to a surface of the glass core 502. In embodiments, the over mold 570 fills in the volume around the edges of the die 520. In embodiments, the over mold 570 may be an ABF dielectric or a photo definable mold.

FIG. 5E illustrates a stage in the manufacturing process where a drilling process is used to drill through the over mold 570 to expose the copper 508, electrical contacts 524, and a copper plating process is applied to form copper pads 509, 527. Note that this process may involve a laser drill or lithographic opening when a photo definable mold is used to form copper pads 509, 527. Note that, in embodiments, at this stage an RDL (not shown) may be applied to the surface of the resulting over mold 571 to provide signal or power routing.

In other embodiments, the stages described above with respect to FIG. 5D-5E may instead include applying a planarization process to FIG. 5C to expose the copper 508 and electrical connections 524. Then an overplating process may be applied to form copper pads similar to copper pads 509, 527 as shown in FIG. 5E. An encapsulation with an overmold such as over mold 570 of FIG. 5D may be applied, followed by a reveal with CMP to expose the copper connections 509, 527.

FIG. 5F illustrates a stage in the manufacturing process where a solder resist (SR) layer 572 is applied and openings 574 are created, and subsequently filled with copper (not shown). In embodiments, the openings 574 may be created by lithography or laser process. In embodiments, the SR layer 572 may be a generic surface insulator such as polyimide.

FIG. 5G illustrates a stage in the manufacturing process that begins an FLI creation process and an active die assembly process. In embodiments, FLI pads 576 are applied, which may be similar to FLI layer 460 of FIG. 4. Dies 562, 564, which may be similar to dies 462, 464 of FIG. 4, are also applied. Subsequently, an under fill 578 may then be applied.

FIG. 5H illustrates a stage in the manufacturing process where chiplets 566 are applied, and a molding 580 is applied. In embodiments, the stage may involve back grinding and metallization processes to apply the chiplets 566. Note that chiplets 566 need not be assembled onto dies 562; but dies 562 may themselves be the final, active chiplets used in the complete assembly.

FIG. 5I illustrates a stage in the manufacturing process where the package may be flipped and the glass carrier 510 and LRL 507 are removed. In embodiments, the LRL 507 may be debonded, typically by a laser ablation or thermal release process, and a wet or dry clean may be applied to remove any residual LRL 507. At this point, an MLI interface including bumps (not shown) may be created for mounting on another substrate (not shown). In embodiments, at this stage and RDL (not shown) may be formed on the side of the glass core 502.

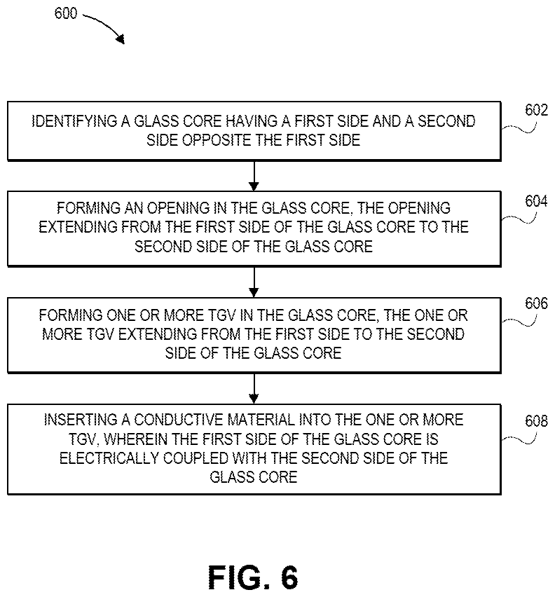

FIG. 6 illustrates an example of a process for creating a glass core with one or more openings and one or more TGV filled with conductive material, in accordance with various embodiments. Process 600 may be performed by one or more elements, techniques, processes or systems that may be described herein, and in particular with respect to FIGS. 1-5I.

At block 602, the process may include identifying a glass core having a first side and a second side opposite the first side. In embodiments, the glass core may be similar to glass core 102 of FIG. 1, 202 of FIG. 2, 402 of FIG. 4, or 502 of FIG. 5B-5I.

At block 604, the process may further include forming an opening in the glass core, the opening extending from the first side of the glass core to the second side of the glass core. In embodiments, the opening in the glass core may be similar to openings 104 of FIG. 1, 204, 234, 236, 240, 264 of FIG. 2, or 504 of FIG. 5B.

At block 606, the process may further include forming one or more TGV in the glass core, the one or more TGV extending from the first side to the second side of the glass core. In embodiments, the TGVs may be similar to TGVs 106 of FIG. 1, or 506 of FIG. 5B.

At block 608, the process may further include inserting a conductive material into the one or more TGV, wherein the first side of the glass core is electrically coupled with the second side of the glass core. In embodiments, the conductive material may be similar to conductive material 108 of FIG. 1, 408 of FIG. 4, and 508 of FIG. 5B.

FIG. 7 illustrates multiple examples of laser-assisted etching of glass interconnects processes, in accordance with embodiments. FIG. 7 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 700 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 712 is created by laser pulses from two laser sources 702, 704 on opposite sides of a glass wafer 706. As used herein, a through drill and a through via refers to when the drill or the via starts on one side of the glass/substrate and ends on the other side. A blind drill and a blind via refers to when the drill or the via starts on the surface of the substrate and stops half way inside the substrate. In embodiments, the laser pulses from the two laser sources 702, 704 are applied perpendicularly to the glass wafer 706 to induce a morphological change 708, which may also be referred to as a structural change, in the glass that encounters the laser pulses. This morphological change 708 includes changes in the molecular structure of the glass to make it easier to etch out (remove a portion of the glass). In embodiments, a wet etch process may be used.

Diagram 720 shows a high level process flow for a double blind shape. A double blind shape 732, 733 may be created by laser pulses from two laser sources 722, 724, which may be similar to laser sources 702, 704, that are on opposite sides of the glass wafer 726, which may be similar to glass wafer 706. In this example, adjustments may be made in the laser pulse energy and/or the laser pulse exposure time from the two laser sources 722, 724. As a result, morphological changes 728, 729 in the glass 726 may result, with these changes making it easier to etch out portions of the glass. In embodiments, a wet etch process may be used.

Diagram 740 shows a high level process flow for a single-blind shape, which may also be referred to as a trench. In this example, a single laser source 742 delivers a laser pulse to the glass wafer 746 to create a morphological change 748 in the glass 746. As described above, these morphological changes make it easier to etch out a portion of the glass 752. In embodiments, a wet etch process may be used.

Diagram 760 shows a high level process flow for a through via shape. In this example, a single laser source 762 applies a laser pulse to the glass 766 to create a morphological change 768 in the glass 766, with the change making it easier to etch out a portion of the glass 772. As shown here, the laser pulse energy and/or laser pulse exposure time from the laser source 762 has been adjusted to create an etched out portion 772 that extends entirely through the glass 766.

With respect to FIG. 7, although embodiments show laser sources 702, 704, 722, 724, 742, 762 as perpendicular to a surface of the glass 706, 726, 746, 766, in embodiments, the laser sources may be positioned at an angle to the surface of the glass, with pulse energy and/or pulse exposure time variations in order to cause a diagonal via or a trench, or to shape the via, such as 712, 772, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 7, through hole vias 712, 772 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias will result in better signaling, allowing more I/O signals to be put through the glass wafer and to other coupled components such as a substrate.

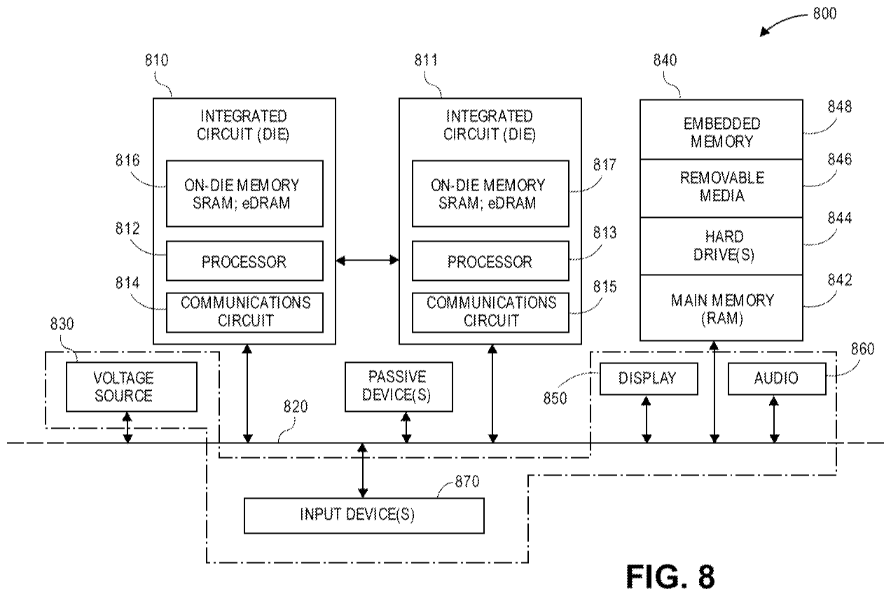

FIG. 8 is a schematic of a computer system 800, in accordance with an embodiment of the present invention. The computer system 800 (also referred to as the electronic system 800) as depicted can embody a glass core that includes openings and TGV, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, a glass core that includes openings and TGV, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having a glass core that includes openings and TGV, according to any of the several disclosed embodiments and their equivalents, an electronic system, a computer system, one or more methods of fabricating an integrated circuit, and one or more methods of fabricating an electronic assembly that includes a package substrate having a glass core that includes openings and TGV, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a glass core that includes openings and TGV embodiments and their equivalents. A foundation substrate may be included, as represented by the dashed line of FIG. 8. Passive devices may also be included, as is also depicted in FIG. 8.

### EXAMPLES

The following paragraphs describe examples of various embodiments.

Example 1 is an apparatus, comprising: a glass core with a first side and a second side opposite the first side; an opening in the glass core extending from the first side to the second side; and one or more through glass vias (TGV) proximate to the opening, the one or more TGV extending from the first side to the second side of the glass core, wherein the one or more TGV include an electrically conductive material that electrically couples the first side of the glass core with the second side of the glass core.

Example 2 may include the apparatus of example 1, or of any other example or embodiment described herein, wherein the electrically conductive material includes copper.

Example 3 may include the apparatus of example 1, or of any other example or embodiment described herein, wherein the one or more TGV are filled with an electrically conductive material.

Example 4 may include the apparatus of example 1, or of any other example or embodiment described herein, wherein a diameter of one of the one or more TGV is less than 25 μm, and wherein a pitch of the one or more TGV is less than 50 μm.

Example 5 may include the apparatus of example 1, or of any other example or embodiment described herein, further comprising a die with a first side and a second side opposite the first side, the die disposed within the opening of the glass core.

Example 6 may include the apparatus of example 5, or of any other example or embodiment described herein, wherein a first distance between the first side and the second side of the first die perpendicular to the first side of the first die, and a second distance between the first side of the second side of the glass core perpendicular to the first side of the glass core are substantially the same.

Example 7 may include the apparatus of example 5, or of any other example or embodiment described herein, wherein a value of a coefficient of thermal expansion (CTE) of the die and a value of a CTE of the glass core are substantially a same value.

Example 8 may include the apparatus of example 5, or of any other example or embodiment described herein, wherein the first side of the glass core and the first side of the die are on a substrate.

Example 9 may include the apparatus of example 5, or of any other example or embodiment described herein, wherein the die is a plurality of dies

Example 10 may include the apparatus of example 1, or of any other example or embodiment described herein, wherein the opening is a plurality of openings.

Example 11 may include the apparatus of example 1, or of any other example or embodiment described herein, wherein the opening is surrounded by the glass core.

Example 12 may include the apparatus of example 1, or of any other example or embodiment described herein, wherein the opening is at an edge of the glass core.

Example 13 is a method comprising: identifying a glass core having a first side and a second side opposite the first side; forming an opening in the glass core, the opening extending from the first side of the glass core to the second side of the glass core; forming one or more through glass vias (TGV) in the glass core, the one or more TGV extending from the first side to the second side of the glass core; and inserting a conductive material into the one or more TGV, wherein the first side of the glass core is electrically coupled with the second side of the glass core.

Example 14 may include the method of example 13, or of any other example or embodiment described herein, wherein the conductive material includes copper.

Example 15 may include the method of example 13, or of any other example or embodiment described herein, wherein a diameter of one of the one or more TGV is less than 25 μm, and wherein a pitch of the one or more TGV is less than 50 μm.

Example 16 may include the method of example 13, or of any other example or embodiment described herein, further comprising inserting a die having a first side and a second side opposite the first side into the opening of the glass core, wherein the first side of the die is proximate to the first side of the glass core, and the second side of the die is proximate to the second side of the glass core.

Example 17 may include the method of example 16, or of any other example or embodiment described herein, wherein a thickness of the die is approximate to a thickness of the glass core.

Example 18 may include the method of example 16, or of any other example or embodiment described herein, further comprising: attaching the second side of the glass core to a carrier; and attaching the second side of the die to the carrier.

Example 19 may include the method of example 16, or of any other example or embodiment described herein, wherein the first side of the die includes one or more electrical connections; and further comprising: forming an insulation layer on top of the first side of the die and the first side of the glass core; and forming one or more electrical contacts that extend through the insulation layer, the one or more electrical contacts electrically coupled, respectively, with the one or more TGV and the one or more electrical connections on the first side of the die.

Example 20 may include the method of example 16, or of any other example or embodiment described herein, wherein inserting a die having the first side and the second side opposite the first side into the opening of the glass core further includes inserting a plurality of dies, each having a first side and a second side opposite the first side into the opening of the glass core.

Example 21 may include the method of example 13, or of any other example or embodiment described herein, wherein forming an opening in the glass core further includes forming a plurality of openings in the glass core.

Example 22 is a package comprising: an interposer comprising: a glass core with a first side and a second side opposite the first side; an opening in the glass core extending from the first side to the second side; one or more through glass vias (TGV) proximate to the opening, the one or more TGV extending from the first side to the second side of the glass core, wherein the one or more TGV include an electrically conductive material that electrically couples the first side of the glass core with the second side of the glass core; and a first die with a first side and a second side opposite the first side, the first die disposed within the opening of the glass core, wherein the first side of the first die is proximate to the first side of the glass core, and the second side of the first die is proximate to the second side of the glass core, and wherein a first side of the first die includes one or more electrical connections; and a second die electrically coupled with at least one of the TGV and electrically coupled with at least one of the one or more electrical connections of the first die, the second die physically coupled with the interposer.

Example 23 may include the package of example 22, or of any other example or embodiment described herein, further comprising a third die electrically coupled with at least one of the TGV and electrically coupled with at least one of the one or more electrical connections of the first die, the third die physically coupled with the interposer.

Example 24 may include the package of example 22, or of any other example or embodiment described herein, wherein the opening in the glass core of the interposer is at an edge of the glass core.

Example 25 may include the package of example 22, or of any other example or embodiment described herein, wherein the electrically conductive material includes copper.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus, comprising:
a glass core with a first side and a second side opposite the first side;
an opening in the glass core extending from the first side to the second side; and
one or more through glass vias (TGV) proximate to the opening, the one or more TGV extending from the first side to the second side of the glass core, wherein the one or more TGV include an electrically conductive material that electrically couples the first side of the glass core with the second side of the glass core.

2. The apparatus of claim 1, wherein the electrically conductive material includes copper.

3. The apparatus of claim 1, wherein the one or more TGV are filled with an electrically conductive material.

4. The apparatus of claim 1, wherein a diameter of one of the one or more TGV is less than 25 μm, and wherein a pitch of the one or more TGV is less than 50 μm.

5. The apparatus of claim 1, further comprising a die with a first side and a second side opposite the first side, the die disposed within the opening of the glass core.

6. The apparatus of claim 5, wherein a first distance between the first side and the second side of the first die perpendicular to the first side of the first die, and a second distance between the first side of the second side of the glass core perpendicular to the first side of the glass core are substantially the same.

7. The apparatus of claim 5, wherein a value of a coefficient of thermal expansion (CTE) of the die and a value of a CTE of the glass core are substantially a same value.

8. The apparatus of claim 5, wherein the first side of the glass core and the first side of the die are on a substrate.

9. The apparatus of claim 5, wherein the die is a plurality of dies.

10. The apparatus of claim 1, wherein the opening is a plurality of openings.

11. The apparatus of claim 1, wherein the opening is surrounded by the glass core.

12. The apparatus of claim 1, wherein the opening is at an edge of the glass core.

13. A method comprising:
identifying a glass core having a first side and a second side opposite the first side;
forming an opening in the glass core, the opening extending from the first side of the glass core to the second side of the glass core;
forming one or more through glass vias (TGV) in the glass core, the one or more TGV extending from the first side to the second side of the glass core; and
inserting a conductive material into the one or more TGV, wherein the first side of the glass core is electrically coupled with the second side of the glass core.

14. The method of claim 13, wherein the conductive material includes copper.

15. The method of claim 13, wherein a diameter of one of the one or more TGV is less than 25 μm, and wherein a pitch of the one or more TGV is less than 50 μm.

16. The method of claim 13, further comprising inserting a die having a first side and a second side opposite the first side into the opening of the glass core, wherein the first side of the die is proximate to the first side of the glass core, and the second side of the die is proximate to the second side of the glass core.

17. The method of claim 16, wherein a thickness of the die is approximate to a thickness of the glass core.

18. The method of claim 16, further comprising:
attaching the second side of the glass core to a carrier; and
attaching the second side of the die to the carrier.

19. The method of claim 16, wherein the first side of the die includes one or more electrical connections; and further comprising:
forming an insulation layer on top of the first side of the die and the first side of the glass core; and
forming one or more electrical contacts that extend through the insulation layer, the one or more electrical contacts electrically coupled, respectively, with the one or more TGV and the one or more electrical connections on the first side of the die.

20. The method of claim 16, wherein inserting a die having the first side and the second side opposite the first side into the opening of the glass core further includes inserting a plurality of dies, each having a first side and a second side opposite the first side into the opening of the glass core.

21. The method of claim 13, wherein forming an opening in the glass core further includes forming a plurality of openings in the glass core.

22. A package comprising:
an interposer comprising:
a glass core with a first side and a second side opposite the first side;
an opening in the glass core extending from the first side to the second side;
one or more through glass vias (TGV) proximate to the opening, the one or more TGV extending from the first side to the second side of the glass core, wherein the one or more TGV include an electrically conductive material that electrically couples the first side of the glass core with the second side of the glass core; and
a first die with a first side and a second side opposite the first side, the first die disposed within the opening of the glass core, wherein the first side of the first die is proximate to the first side of the glass core, and the second side of the first die is proximate to the second side of the glass core, and wherein a first side of the first die includes one or more electrical connections; and
a second die electrically coupled with at least one of the TGV and electrically coupled with at least one of the one or more electrical connections of the first die, the second die physically coupled with the interposer.

23. The package of claim 22, further comprising a third die electrically coupled with at least one of the TGV and electrically coupled with at least one of the one or more electrical connections of the first die, the third die physically coupled with the interposer.

24. The package of claim 22, wherein the opening in the glass core of the interposer is at an edge of the glass core.

25. The package of claim 22, wherein the electrically conductive material includes copper.
